(19) United States
(12) Patent Application Publication
(10) Pub. No.: US 2012/0025228 A1
(43) Pub. Date: Feb. 2, 2012

(54) LIGHT-EMITTING DEVICE WITH TEMPERATURE COMPENSATION

(76) Inventors: Min-Hsun HSIEH, Hsinchu (TW); Chien-Yuan Wang, Hsinchu (TW)

(21) Appl. No.: 13/192,997

(22) Filed: Jul. 28, 2011

(30) Foreign Application Priority Data
Jul. 28, 2010 (TW) 099125241

(51) Int. Cl. H01L 33/08; H01L 33/64

(52) U.S. Cl. 257/89; 257/E33.075

(57) ABSTRACT

The present application provides a light-emitting device comprising a light-emitting diode group, a temperature compensation element electrically connected to the light-emitting diode group. When a junction temperature of the light-emitting diode group is increased from a first temperature to a second temperature during operation, the current flowing through the light-emitting diode group at the second temperature is larger than the current flowing through the light-emitting diode group at the first temperature.

### TECHNICAL FIELD

The application relates to a light-emitting device, and more particularly, to a light-emitting device with temperature compensation.

### REFERENCE TO RELATED APPLICATION

This application claims the right of priority based on Taiwan application Serial No. 099125241, filed on Jul. 28, 2010, and the content of which is hereby incorporated by reference.

### DESCRIPTION OF BACKGROUND ART

The light-emitting principle of light-emitting diode (LED) is to use the energy difference of the electrons moving between n-type semiconductor and p-type semiconductor, and the energy is released in the form of the light. This is different from the light-emitting principle of incandescent lamp, so LED is called the cold light source.

Furthermore, LED has the advantages of high durability, long life, light weight, and low power consumption. Today, LED is highly appreciated in lighting market and is regarded as a new generation of lighting tools, so it has gradually replaced traditional lightings, and is used in various fields such as traffic signal, backlight module, street lighting, and medical equipment.

In the application of lighting field, the near sunlight (white color light) spectrum emitted from LED is required to match human's visual habits. The white color light described above can be generated by mixing the three primary colors of red, blue, and green emitted from LED in different ratios through the deployment of operating current by the circuit design. Because the cost of circuit module is high, the method is not widespread. Another method uses ultraviolet spectrum light-emitting diode (UV-LED) to excite red, blue, and green phosphors capable of absorbing a part of light emitted by UV-LED and emitting the red color light, the blue color light, and the green color light. The red color light, the blue color light, and the green color light are mixed to generate the white color light. But the luminous efficiency of UV-LED still needs to be improved, the application of the product is not widespread.

Nevertheless, when the electric current is driven into the LED, in addition to the electric energy-photo energy conversion mechanism, part of the electric energy is transformed into the thermal energy, thus causing changes in the photoelectric characteristics. When the junction temperature (Tⱼ) of the LED is increased from 20° C. to 80° C., the curve of the photoelectric characteristics of blue light LED and red light LED is illustrated in FIG. 1. As shown in FIG. 1, the vertical axis represents the relative value of the photoelectric characteristic value at different junction temperatures compared with that at 20° C. junction temperature of the light emitting device, such as light output power (P₀; rhombus symbol), wavelength shift (W_{d}; triangle symbol), and forward voltage (V_{f}; square symbol). The solid line shown in FIG. 1 represents the characteristic curve of the blue light LED, and the dotted line shown in FIG. 1 represents the characteristic curve of the red light LED. When the junction temperature is increased from 20° C. to 80° C., the light output power of the blue light LED drops about 12% and the hot/cold factor is about 0.88; the light output power of the red light LED drops about 37% and the hot/cold factor is about 0.63. Furthermore, in terms of the wavelength shift, there is no big difference between the blue light LED and the red light LED but is only slightly changed with the difference of Tⱼ. In terms of the forward voltage changes, when the junction temperature is increased from 20° C. to 80° C., the decline of the blue light LED and the red light LED is respectively about 7˜0.8%. Namely, the equivalent resistances of the blue light LED and the red light LED decline about 7˜8% under the operation of constant current. As mentioned above, because the temperature dependences of the blue light LED and the red light LED photoelectric characteristics are different, the undesirable phenomenon of the unstable red/blue light output power ratio happens during the period from the initial operation to the steady state. When the warm white light-emitting device comprising the red light LED and the blue light LED is used in the lighting field, the light color instability during the initial state and the steady state owing to the different hot/cold factors of the blue light LED and the red light LED causes the inconvenient when using the lighting.

### SUMMARY OF THE APPLICATION

The present application provides a light-emitting device which comprises a light-emitting diode group comprising a plurality of light-emitting diode units electrically connected to one another; a temperature compensation element electrically connected to the light-emitting diode group described above. When a junction temperature of the light-emitting diode group is increased from a first temperature to a second temperature during operation, the current flowing through the light-emitting diode group at the second temperature is larger than the current flowing through the light-emitting diode group at the first temperature.

### BRIEF DESCRIPTION OF THE DRAWINGS

FIG. 1 illustrates the relationship curve between the junction temperature and the photoelectric characteristics of the light-emitting device;

FIG. 2 is a diagram of the light-emitting device of the first embodiment according to the present application;

FIG. 3 is a diagram of the light-emitting device of the second embodiment according to the present application;

FIG. 4 is a diagram of the light-emitting device of the third embodiment according to the present application;

FIG. 5 is a diagram of the light-emitting device of the fourth embodiment according to the present application;

FIG. 6 is a diagram of the light-emitting device of the fifth embodiment according to the present application;

FIG. 7 is a structure diagram of the light-emitting device of a light-emitting diode group according to the above-described embodiments the present application; and

FIG. 8 is a structure diagram of the light-emitting device according to the fourth embodiment or the fifth embodiment of the present application.

### DETAILED DESCRIPTION OF PREFERRED EMBODIMENTS

The embodiments of the present application are illustrated in detail, and are plotted in the drawings. The same or the similar part is illustrated in the drawings and the specification with the same number.

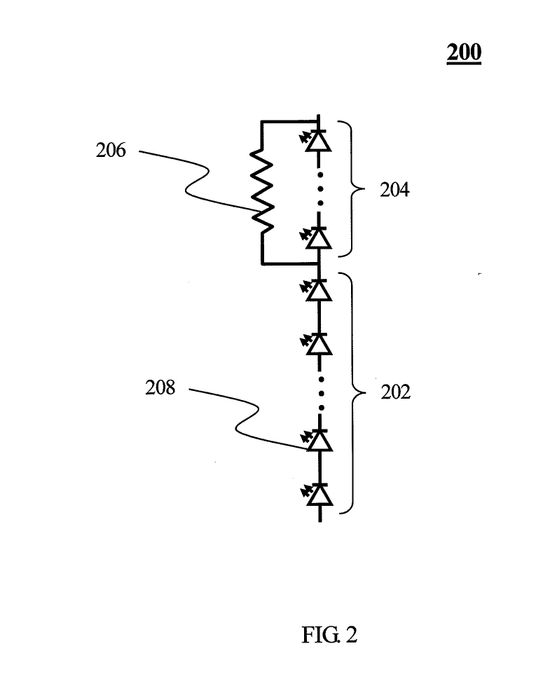

FIG. 2 illustrates an electric circuit diagram of the light-emitting device of the first embodiment according to the present application. The light-emitting device 200 comprises a first light-emitting diode group 202, a second light-emitting diode group 204, and a thermal resistor 206 with positive temperature coefficient. The first light-emitting diode group 202 comprises a first quantity of light-emitting diode units 208 connected to one another in series, the second light-emitting diode group 204 comprises a second quantity of light-emitting diode units 208 connected to one another in series, and the first light-emitting diode group 202 is electrically connected to the second light-emitting diode group 204 in series. The light-emitting diode unit 208 comprises the hot/cold factor no more than 0.9, preferably no more than 0.85, and further preferably no more than 0.8, and comprises a light-emitting diode capable of emitting visible or invisible wavelength, such as red, blue or ultraviolet wavelength light-emitting diodes, or formed by AlGaInP-based material, or GaN-based material. The hot/cold factor means the ratio of the light output power of the light-emitting diode at Tⱼ=80° C. and the light output power of the light-emitting diode at Tⱼ=20° C. when the junction temperature of the light-emitting diode in increased from 20° C. to 80° C.

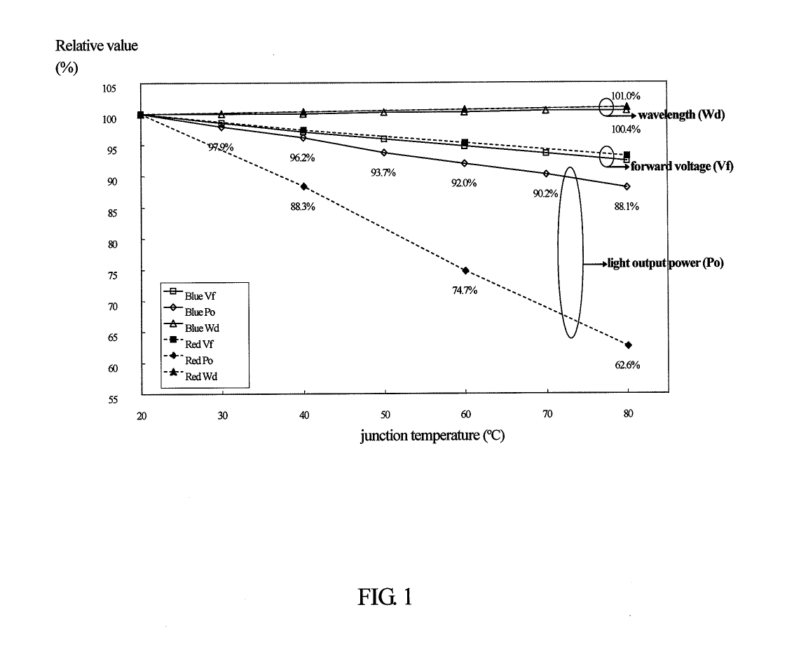

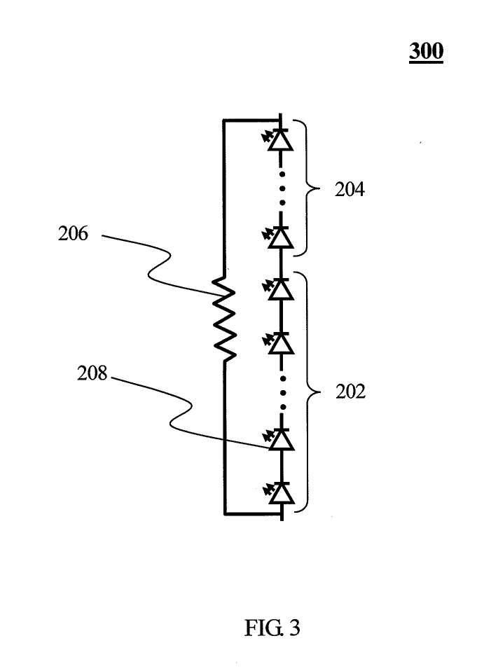

In the embodiment, the second light-emitting diode group 204 is electrically connected to the thermal resistor 206 in parallel. The first light-emitting diode group 202 has an equivalent internal resistance R₁, the second light-emitting diode group 204 has an equivalent internal resistance R₂, and the thermal resistor 206 has a resistance R_{PTC}, wherein R₁ and R₂ decrease when the junction temperature is increased. As shown in FIG. 1, when the light-emitting diode unit 208 is the red light or the blue light light-emitting diode, and Tⱼ is increased from 20° C. to 80° C., R₁ and R₂ respectively decreases about 7˜8%. The resistance R_{PTC} of the thermal resistor 206 with positive temperature coefficient increases in the correlation when the temperature is increased, such as R_{PTC} increases in the linear or the non-linear correlation when the temperature is increased. During the operation of the light-emitting device 200, an electric current I₁ such as 20˜1000 mA flowing through the first light-emitting diode group 202 is divided into I₂ flowing through the second light-emitting diode group 204 and I₃ flowing through the thermal resistor 206 when I₂ flows through the second light-emitting diode group 204 and the thermal resistor 206, wherein I₁=I₂+I₃. In addition, the potential difference of the two terminals of the second light-emitting diode group 204 is equal to the potential difference of the two terminals of the thermal resistor 206. Namely, I₃*R_{PTC}=I₂*R₂. From the above two relationships, the electric current I₂ flowing through the second light-emitting diode group 204 is positive-correlated to R_{PTC}/(R₂+R_{PTC}). Namely, I₂ is respectively positive-correlated to R_{PTC} and negative-correlated to R₂. In the embodiment, the junction temperature of the light-emitting device 200 is increased during operation. For example, the resistance R_{PTC} of the thermal resistor 206 is increased due to the increase of the junction temperature, and the resistance R₂ of the second light-emitting diode group 204 is decreased due to the increase of the junction temperature when the junction temperature is increased from the initial operation first temperature 20° C. to the steady state second temperature 80° C. Therefore, under the constant electric current I₁, the electric current I₂ flowing through the second light-emitting diode group 204 is increased, and the light output power of the second light-emitting diode group 204 is increased due to the increase of I₂. In other words, the light output power of the second light-emitting diode group 204 can be controlled by R_{PTC} to reduce the decline of the light output power of the second light-emitting diode group 204 caused by hot/cold factor when the junction temperature is increased, and the function of the temperature compensation is achieved. In addition, the decline of the light output power of the light-emitting device caused by hot/cold factor during the increase of the junction temperature can be offset or controlled by adjusting the quantity of the light-emitting diode units of the first light-emitting diode group and the second light-emitting diode group, or selecting the thermal resistor with suitable temperature coefficient. As shown in FIG. 3, the thermal resistor 206 of the embodiment can be electrically connected to the first light-emitting diode group 202 and the second light-emitting diode group 204 in parallel at the same time. Thus, the electric current flowing through the first light-emitting diode group 202 and the second light-emitting diode group 204 is increased compared with that at the initial temperature when the junction temperature of the light-emitting device is increased.

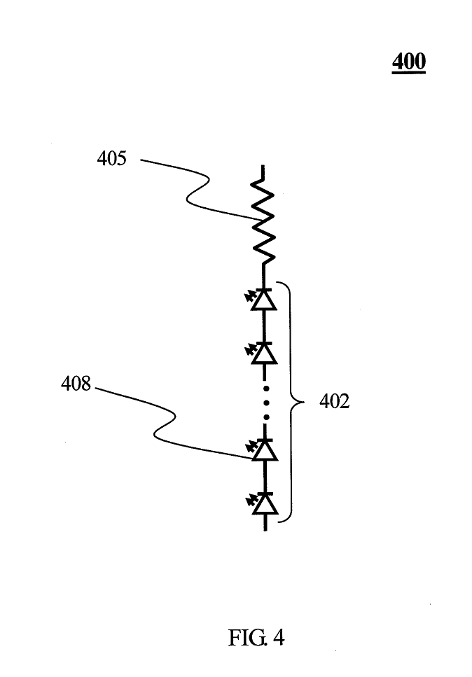

FIG. 4 is an electric circuit diagram of the light-emitting device of the third embodiment according to the present application. The light-emitting device 400 comprises a light-emitting diode group 402 and a thermal resistor 405 with negative temperature coefficient. The light-emitting diode group 402 comprises a plurality of light-emitting diode units 408 connected to one another in series. The light-emitting diode group 402 comprises the light-emitting diode capable of emitting visible or invisible wavelength, such as red, blue or ultraviolet wavelength light-emitting diodes, or formed by AlGaInP-based material, or GaN-based material.

In the embodiment, the light-emitting diode group 402 and the thermal resistor 405 are electrically connected in series. The light-emitting diode group 402 has an equivalent internal resistance R₁, and the thermal resistor 405 has a resistance R_{NTC}, wherein R₁ decreases when the junction temperature is increased. As shown in FIG. 1, when the light-emitting diode unit 408 is the red light or the blue light light-emitting diode, and Tⱼ is increased from 20° C. to 80° C., R₁ decreases about 7˜8%. The resistance R_{NTC} of the thermal resistor 405 with negative temperature coefficient decreases in a correlation when the temperature is increased, such as R_{NTC} decreases in the linear or the non-linear relationship when the temperature is increased. When the light-emitting device 400 is operated under the constant electric voltage, the electric current I₁ flowing through the light-emitting diode group 402 is about 20˜1000 mA under the input Vᵢₙ of constant electric voltage. According to Ohm's law, the electric current I₁ is inversely proportional to the total resistance of the light-emitting device 400 and the input voltage Vᵢₙ, that is, I₁=Vᵢₙ/(R₁=R_{NTC}). In other words, the electric current I₁ flowing through the light-emitting diode group 402 is negative-correlated to R_{NTC} and R₁. In the embodiment, the junction temperature of the light-emitting device 400 is increased during operation. For example, the resistance R_{NTC} of the thermal resistor 405 and the resistance R₁ of the light-emitting diode group 402 are decreased due to the increase of the junction temperature when the junction temperature is increased from the initial operation first temperature 20° C. to the steady state second temperature 80° C. Thus, I₁ is increased, and the light output power of the light-emitting diode group 402 is increased due to the increase of I₁. In other words, the light output power of the light-emitting diode group 402 can be controlled by the R_{PTC} to reduce the decline of the light output power of the light-emitting diode group 402 caused by hot/cold factor when the junction temperature is increased, and the function of the temperature compensation is achieved. In addition, the decline of the light output power of the light-emitting device caused by hot/cold factor during the increase of the junction temperature can be reduced by adjusting the quantity of the light-emitting diode units of the light-emitting diode group 402, and/or selecting the thermal resistor with suitable temperature coefficient.

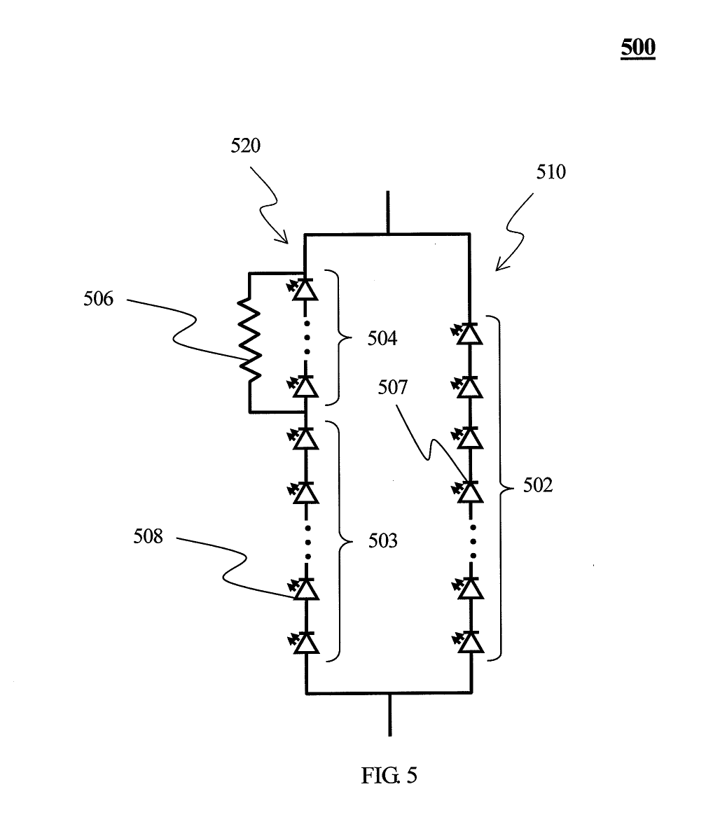

FIG. 5 is an electric circuit diagram of the light-emitting device of the fourth embodiment according to the present application. The light-emitting device 500 comprises a first light-emitting module 510, a second light-emitting module 520 connected to the first light-emitting module 510 in parallel, and a thermal resistor 506 with positive temperature coefficient electrically connected to the second light-emitting module 520. The first light-emitting module 510 comprises a first light-emitting diode group 502, and the second light-emitting module 520 comprises a second light-emitting diode group 503 and a third light-emitting diode group 504. The first light-emitting diode group 502 comprises a first quantity of the first light-emitting diode units 507 connected to one another in series, the second light-emitting diode group 503 comprises a second quantity of the second light-emitting diode units 508 connected to one another in series, and the third light-emitting diode group 504 comprises a third quantity of the second light-emitting diode units 508 connected to one another in series. The thermal resistor 506 is electrically connected to the third light-emitting diode group 504 in parallel, and electrically connected to the second light-emitting diode group 503 in series. The first light-emitting module 510 or the first light-emitting diode unit 507 has the hot/cold factor more than 0.85; the second light-emitting module 520 or the second light-emitting diode unit 508 has the hot/cold factor less than that of the first light-emitting module 510 or the first light-emitting diode unit 507, for example less than 0.85, or preferably less than 0.8. In the embodiment, the first light-emitting diode unit comprises the blue light light-emitting diode with the hot/cold factor about 0.88, and the second light-emitting diode unit comprises the red light light-emitting diode with the hot/cold factor about 0.63. Other visible or invisible wavelength light-emitting diode can also be included, such as green, yellow or ultraviolet wavelength light-emitting diodes, or formed by AlGaInP-based material, or GaN-based material.

In the embodiment, the third light-emitting diode group 504 is electrically connected to the thermal resistor 506 in parallel. The second light-emitting diode group 503 has an equivalent internal resistance R₁, the third light-emitting diode group 504 has an equivalent internal resistance R₂, and the thermal resistor 506 has a resistance R_{PTC}, wherein R₁ and R₂ decrease when the junction temperature is increased. As shown in FIG. 1, when the second light-emitting diode unit is the red light or the blue light light-emitting diode, R₁ and R₂ respectively decreases about 7˜8%. The resistance R_{PTC} of the thermal resistor 506 with positive temperature coefficient increases in the correlation when the temperature is increased, such as R_{PTC} increases in the linear or the non-linear correlation when the temperature is increased. During the operation of the light-emitting device 500, an electric current I₀ is divided into I₁ flowing through the first light-emitting module 510 and I₂ flowing through the second light-emitting module 520. The electric current I₂ flowing through the third light-emitting diode group 504 and the thermal resistor 506 of the second light-emitting module 520 is divided into I₃ flowing through the third light-emitting diode group 504 and I₄ flowing through the thermal resistor 506, wherein I₂=I₃+I₄. In addition, the potential difference of the two terminals of the third light-emitting diode group 504 is equal to the potential difference of the two terminals of the thermal resistor 506. Namely, I₄*R_{PTC}=I₃*R₂. From the above two relationships, the electric current I₃ flowing through the third light-emitting diode group 504 is positive-correlated to R_{PTC}/(R₂+R_{PTC}). Namely, I₃ is positive-correlated to R_{PTC} and negative-correlated to R₂. In the embodiment, the junction temperature of the light-emitting device 500 is increased during operation. For example, the resistance R_{PTC} of the thermal resistor 506 is increased due to the increase of the junction temperature, and the resistance R₂ of the third light-emitting diode group 504 is decreased due to the increase of the junction temperature when the junction temperature is increased from the initial operation first temperature 20° C. to the steady state second temperature 80° C. Therefore, I₃ increases due to the increase of the junction temperature and the light output power of the third light-emitting diode group 504 also increases due to the increase of I₃. In the embodiment, the hot/cold factor of the first light-emitting module 510 is larger than that of the second light-emitting module 520, so the decline of the light output power of the second light-emitting module 520 is larger than that of the first light-emitting module 510 when the junction temperature is increased. Thus, the light color mixed by the light emitted from the first light-emitting module 510 and the light emitted from the second light-emitting module 520 shifts to the light color emitted from the first light-emitting module 510 when the junction temperature is increased. But the decline of the light output power of the second light-emitting module 520 caused by hot/cold factor can be reduced when the junction temperature is increased by controlling the R_{PTC} of the thermal resistor 506, and the function of the temperature compensation can be achieved. In addition, the decline of the light output power of the second light-emitting module caused by hot/cold factor during the increase of the junction temperature can be offset or controlled by adjusting the quantity of the light-emitting diode units of the second light-emitting diode group and the third light-emitting diode group, or selecting the thermal resistor with suitable temperature coefficient. Furthermore, the thermal resistor 506 of the embodiment can be electrically connected to the second light-emitting diode group 503 and the third light-emitting diode group 504 in parallel at the same time. Thus, the electric current flowing through the second light-emitting diode group 503 and the third light-emitting diode group 504 is increased compared with that at the initial temperature when the junction temperature of the light-emitting device is increased.

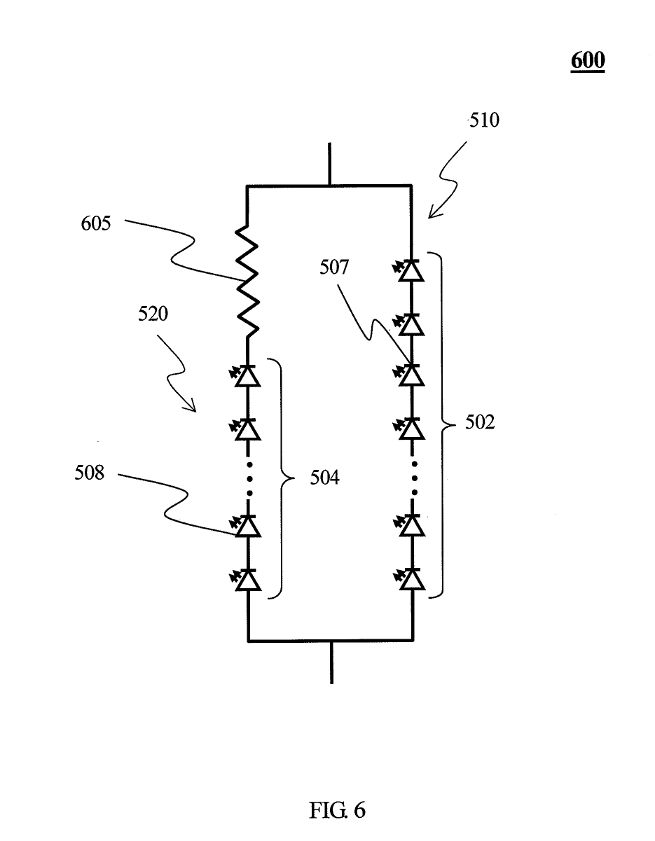

The fifth embodiment of the present application is illustrated in FIG. 6. The difference between the fifth and the fourth embodiments is that the second light-emitting module 520 is connected to the thermal resistor 605 with negative temperature coefficient in series. Based on the related description similar to the third embodiment and the fourth embodiment, the function of temperature compensation of the present application is achieved. In addition, the first light-emitting module and the second light-emitting module of the above-described fourth and fifth embodiments are not limited to be connected in parallel, and each of them also can be connected to an independent control current source or voltage source.

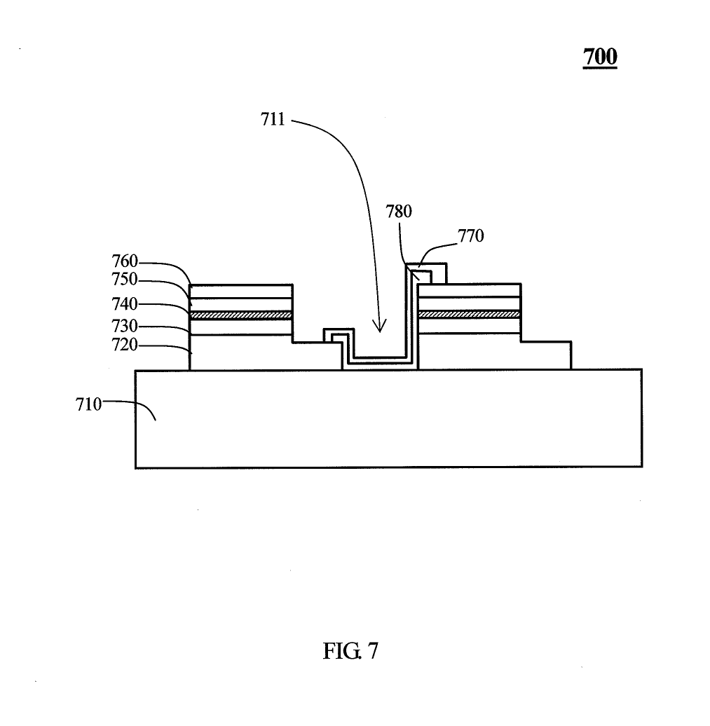

FIG. 7 is a structure diagram of a light-emitting diode group according to the above-described embodiments of the present application. A light-emitting diode group 700 comprises a substrate 700, and a plurality of light-emitting diode units formed or attached to the substrate 700 in an array type, and is divided by a trench 711. Each of the plurality of light-emitting diode units comprises an n-type contact layer 720 formed on the substrate 710, an n-type cladding layer 730 formed on the contact layer 720, an active layer 740 formed on the n-type cladding layer 730, a p-type cladding layer 750 formed on the active layer 740, a p-type contact layer 760 formed on the p-type cladding layer 750, a connecting wire 770 electrically connected to the n-type contact layer 720 of the light-emitting diode unit and the p-type contact layer 760 of another light-emitting diode unit in series, and an insulation layer 780 formed between the trench 711 and the connecting wire 770 to avoid the short circuit path. In the embodiment of the present application, the light-emitting diode group 700 comprises a high voltage array-type single chip including the plurality of light-emitting diode units collectively formed on the single substrate, such as the blue light high voltage array-type single chip or the red light high voltage array-type single chip, and the operation voltage depends on the quantity of the light-emitting diode units connected in series. The material of the above-described n-type or p-type contact layer, the n-type or the p-type cladding layer, or the active layer comprises the III-V group compound such as AlₓIn_{y}Ga_{(1-x-y)}N or AlₓIn_{y}Ga_{(1-x-y)}P, wherein 0≦x, y≦1; (x+y)≦1.

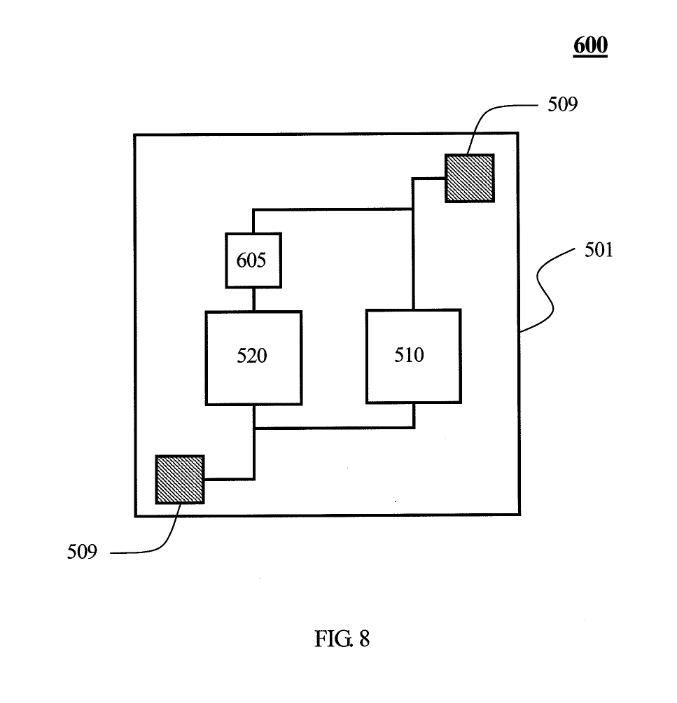

FIG. 8 is a structure diagram of the light-emitting device according to the fourth embodiment or the fifth embodiment of the present application. The first light-emitting module 510 of the light-emitting device 600 comprises the blue light high voltage array-type single chip illustrated in FIG. 7, and the second light-emitting module 520 comprising the red light high voltage array-type single chip illustrated in FIG. 7 is electrically connected to a thermal resistor 605; two electrodes 509 are electrically connected to the first light-emitting module 510 and the second light-emitting module 520 to receive a power signal; the first light-emitting module 510, the second light-emitting module 520, the thermal resistor 605 and the electrode 509 are collectively formed on a board 501.

The principle and the efficiency of the present application illustrated by the embodiments above are not the limitation of the present application. Any person having ordinary skill in the art can modify or change the aforementioned embodiments. Therefore, the protection range of the rights in the present application will be listed as the following claims.

What is claimed is:

1. A light-emitting device, comprising:
a first light-emitting diode group with a first hot/cold factor comprising a plurality of first light-emitting diode units electrically connected to one another, wherein the junction temperature of the first light-emitting diode group is increased from a first temperature to a second temperature during operation; and
a temperature compensation element electrically connected to the first light-emitting diode group so the current flowing through the first light-emitting diode group at the second temperature is larger than the current flowing through the first light-emitting diode group at the first temperature.

2. The light-emitting device as claimed in claim 1, wherein the temperature compensation element is a thermal resistor with positive temperature coefficient, and is connected to the first light-emitting diode group in parallel.

3. The light-emitting device as claimed in claim 1, wherein the temperature compensation element is a thermal resistor with negative temperature coefficient, and is connected to the first light-emitting diode group in series.

4. The light-emitting device as claimed in claim 1, wherein the first light-emitting diode unit is a red light light-emitting diode.

5. The light-emitting device as claimed in claim 1, wherein the first light-emitting diode group comprises a substrate, and the first light-emitting diode units are collectively formed on the substrate to form a high voltage single chip.

6. The light-emitting device as claimed in claim 1 further comprising a board, wherein the first light-emitting diode group is formed on the board.

7. The light-emitting device as claimed in claim 6 further comprising a second light-emitting diode group formed on the board, having a second hot/cold factor larger than the first hot/cold factor, and comprising a plurality of second light-emitting diode units electrically connected to one another.

8. The light-emitting device as claimed in claim 1, wherein the first hot/cold factor is no more than 0.85.

9. The light-emitting device as claimed in claim 7, wherein the second hot/cold factor is not less than 0.85.

10. The light-emitting device as claimed in claim 7, wherein the second light-emitting diode unit is a blue light light-emitting diode.

11. The light-emitting device as claimed in claim 7, wherein the second light-emitting diode group comprises a substrate, and the second light-emitting diode units are collectively formed on the substrate to form a high voltage single chip.

12. The light-emitting device as claimed in claim 7, wherein the first light-emitting diode group is electrically connected to the second light-emitting diode group.

13. The light-emitting device as claimed in claim 6, wherein the temperature compensation element is formed on the board.
